(19) United States
(12) Patent Application Publication
(10) Pub. No.: US 2012/0176144 A1
(43) Pub. Date: Jul. 12, 2012

(54) AT-SPEED SCAN ENABLE SWITCHING CIRCUIT

(75) Inventors: Vikram Iyengar, Pittsburgh, PA (US); Animesh Khare, Bangalore (IN); Michael R. Ouellette, Westford, VT (US); Narendra K. Rane, Bangalore (IN); Umesh K. Shukla, Bangalore (IN); Pradeep K. Vanama, Bangalore (IN)

(73) Assignee: INTERNATIONAL BUSINESS MACHINES CORPORATION, Armonk, NY (US)

(21) Appl. No.: 12/986,546

(22) Filed: Jan. 7, 2011

(51) Int. Cl. G01R 27/28; H01L 25/00

(52) U.S. Cl. 324/617; 327/566

(57) ABSTRACT

A circuit for providing a local scan enable signal includes a first transistor having a first gate coupled to a general scan enable signal, a first source and a first drain and a second transistor having a second gate coupled to a scan clock, a second source coupled to the first drain and a second drain. The circuit also includes a third transistor having a third gate coupled to the general scan enable signal, a third drain coupled to the second drain and a third source and an output stabilizer coupled to the second drain, the output stabilizer including a first inverter and a second inverter coupled together in opposite orientations.

### BACKGROUND

The present invention relates to electrical circuits, and more specifically, to an electrical circuit that provides an at-speed scan enable signal.

With the development of nanometer semiconductor technologies, manufacturing defects that create timing errors but that do not result in catastrophic functional failures are becoming more common. Traditional “stuck-at” tests alone can no longer fully verify functionality of fabricated integrated circuits. As such, at-speed testing of integrated circuits is becoming critical to detect delay defects.

Traditional functional at-speed tests suffer from increasing test design costs, especially when the scale of the design is in the millions of gates. Furthermore, in SOC (System-on-Chip) designs, limited test access to internal cores makes application of at-speed tests difficult or impractical. One approach to testing SOC designs is to perform scan-based at-speed testing. Such testing can significantly improve the controllability and observability of internal signals in SOCs.

In a scan-based at-speed test, a scan pattern is shifted into the circuit under test (CUT). Then, the scan-enable signal that configures the flip-flops in the scan chain is toggled for a single clock cycle to allow for the capture of the CUT's response to the scan pattern. The flip-flops then return to the scan configuration so that the captured response data can be shifted out. The provision of such signals typically requires that an additional circuit be provided.

In more detail, to perform an at-speed test, a pattern pair (V1, V2) is applied to the CUT. Pattern V1 is termed as the initialization pattern and V2 as the launch pattern. The response of the CUT to the pattern V2 is captured at the data output of the CUT at functional speed (i.e., rated clock speed).

Referring now to FIG. 1A, such a test can be divided into 3 cycles: 1) an Initialization Cycle (IC), where the CUT is initialized to a particular state (i.e., V1 is applied); 2) a Launch Cycle (LC), where a transition is launched into the CUT (V2 is applied); and 3) Capture Cycle (CC), where the transition is propagated and captured at an observation point (e.g., the data output of the CUT).

In FIG. 1A, the relationship between a testing clock (CLK), the general scan enable signal (GSE) and the local scan enable (LSE) are displayed. One of skill in the art will realize that the timing of the transition of the GSE signal is typically determined based on an industry standard. The relationship shown in FIG. 1A is utilized in a so-called launch-off-shift (LOS) method. In the LOS method, the LSE signal is provided to a selector (multiplexer) that determines whether data or a scan value will be provided to an output latch of the CUT. Of course, such an approach could also be applied to the context of an LSSD (Level-Sensitive Scan Design).

The LC is a part of the shift operation and is immediately followed by a fast capture pulse 102. The local scan enable (LSE) is high during the last shift (e.g., at pulse 101) and must go low to enable response capture at the CC clock edge (pulse 102). The time period for LSE to make this “1” to “0” transition corresponds to the functional frequency. Hence, LOS requires the LSE signal to be timing critical.

FIG. 1B illustrates the waveforms (CLK and GSE) of a second approach to at-speed testing, referred to as launch-off-capture (LOC). In the LOC method, the launch cycle is separated from the shift operation. At the end of scan-in (IC), pattern V1 is applied and the CUT is set to an initialized state. A pair of at-speed clock pulses 104, 106 are applied to launch and capture the transition at the output of the CUT. An LOC test methodology has relaxed at-speed constraints as compared to the constraint on the LSE signal described above because dead cycles are added after the last shift to provide enough time for the GSE signal to settle low.

In practice, the LOS method is preferable based on ATPG (Automatic Test Pattern Generation) complexity and pattern count compared to the LOC method. In the case of the LOC methodology, high fault coverage cannot be guaranteed due to the correlation between the two patterns, V1 and V2.

FIG. 2 shows an example of a circuit 200 for producing an output signal LSE based on a GSE signal and the test clock CLK. This circuit 200 provides the local shift enable (LSE) signal to the selection input of a multiplexer 201 that forms part of a multiplexed-D flip-flop assembly. Such a multiplexed-D flip-flop assembly is commonly used in scan testing.

In general terms, the circuit 200 is composed of scan enable circuit 202 and two inverters 208 and 210. In particular, the test clock (CLK) is coupled to clock inverter 208. The output of clock inverter 208 (CLK*) is provided to AND gate 204. The other input to the AND gate 204 is the output of the circuit 200, referred to as LSE. The output of AND gate 204 and the GSE signal are provided as inputs to NOR gate 206. The output of NOR gate 206 is provided to inverter 208 to produce the LSE. As one of ordinary skill will understand, the LSE signal can be provided as the selector to an input/output selector for a CUT.

The circuit 200 in FIG. 2 includes 10 CMOS transistors. In particular, the exploded version of the scan enable circuit 202 illustrates that the AND gate 204 and the NOR gate 206, collectively, comprise six CMOS transistors T1-T6. In addition, each of the inverters 208, 210 are formed by two CMOS (1 PMOS and 1 NMOS) transistors as is known in the art.

### SUMMARY

According to one embodiment of the present invention, a circuit for providing a local scan enable signal is disclosed. The circuit of this embodiment includes a first transistor having a first gate coupled to a general scan enable signal, a first source and a first drain and a second transistor having a second gate coupled to a scan clock, a second source coupled to the first drain and a second drain. The circuit of this embodiment also includes a third transistor having a third gate coupled to the general scan enable signal, a third drain coupled to the second drain and a third source. The circuit of this embodiment also includes an output stabilizer coupled to the second drain, the output stabilizer includes a first inverter and a second inverter coupled together in opposite orientations.

According to another embodiment, a circuit for providing a local scan enable signal is disclosed. The circuit of this embodiment includes a first transistor having a first gate coupled to a general scan enable signal, a first source and a first drain and a second transistor having a second gate coupled to a scan clock, a second drain coupled to the first drain and a second source. The circuit of this embodiment also includes a third transistor having a third gate coupled to the general scan enable signal, a third drain coupled to the second source and a third source. In addition, the circuit of this embodiment includes an output stabilizer coupled to the first drain, the output stabilizer including a first inverter and a second inverter coupled together in opposite orientations.

According to yet another embodiment, a test system that includes a first circuit for providing a local scan enable signal is disclosed. In this embodiment, the first circuit includes a first transistor having a first gate coupled to a general scan enable signal, a first source and a first drain, a second transistor having a second gate coupled to a scan clock, a second source coupled to the first drain and a second drain and a third transistor having a third gate coupled to the general scan enable signal, a third drain coupled to the second drain and a third source. The first circuit also includes an output stabilizer coupled to the second drain, the output stabilizer including a first inverter and a second inverter coupled together in opposite orientations. The test system of this embodiment also includes a second circuit for providing the general scan enable signal, the second circuit configured to provide the general scan enable signal according to a first timing relationship when the first circuit is operating in a launch off scan mode and a second timing relationship when the first circuit is operating in a launch off capture mode.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIGS. 1A and 1B, respectively, illustrate timing diagrams for LOS and LOC testing methods;

FIG. 2 illustrates a circuit for generating a local scan enable signal according to the prior art;

FIG. 3 illustrates a circuit for generating a local scan enable signal according to one embodiment of the present invention;

FIG. 4 is a timing diagram for the circuit illustrated in FIG. 3;

FIG. 5 illustrates a circuit for generating a local scan enable signal for both LOS and LOC testing methods according to one embodiment of the present invention;

FIG. 6 illustrates an alternative circuit for generating a local scan enable signal for both LOS and LOC testing methods according to one embodiment of the present invention;

FIG. 7 illustrates a circuit for providing a scan signal to an LSSD circuit;

FIG. 8 illustrates two different timing possibilities for a GSE signal according to embodiments of the present invention; and

FIG. 9 shows an alternative embodiment of the invention than as shown in FIG. 3 where the weak inverter has been replaced with an alternative feedback element.

### DETAILED DESCRIPTION

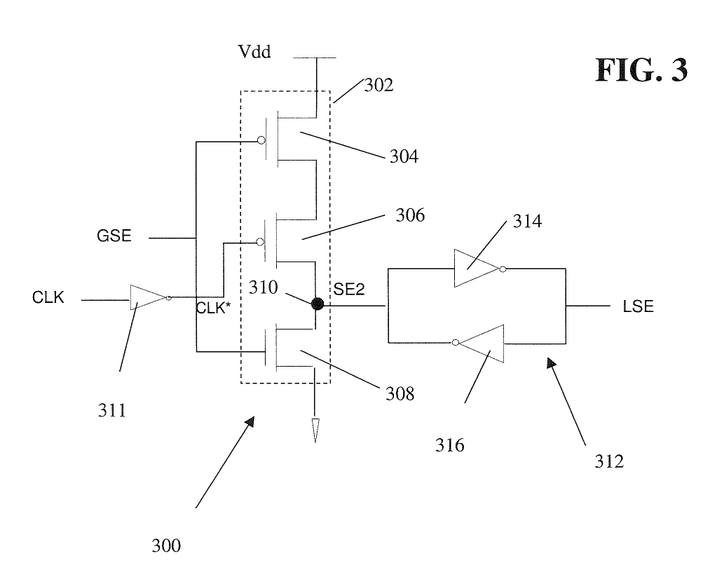

FIG. 3 illustrates an example of local scan enable circuit 300 that may be utilized to provide an at-speed switching of a local scan enable signal. Such a signal is referred to as LSE herein.

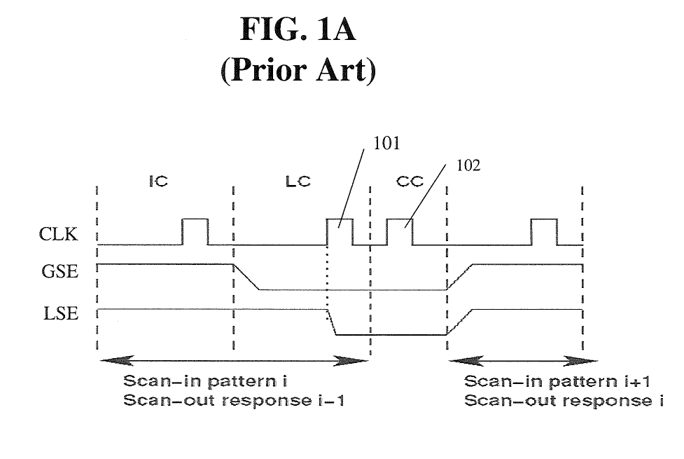

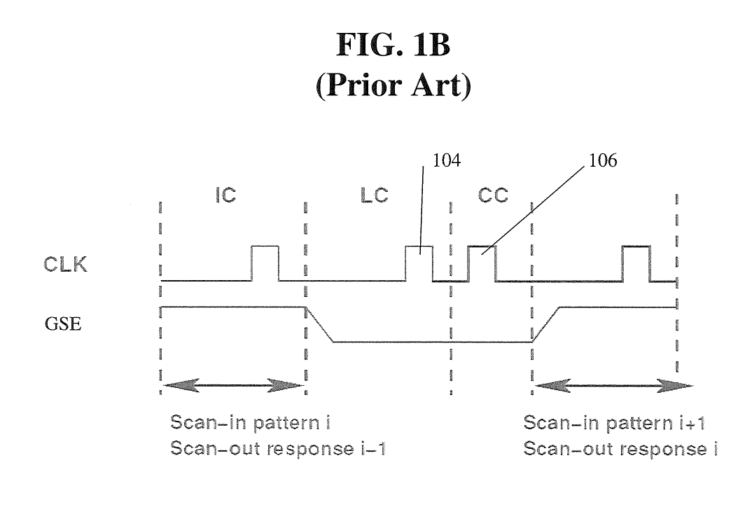

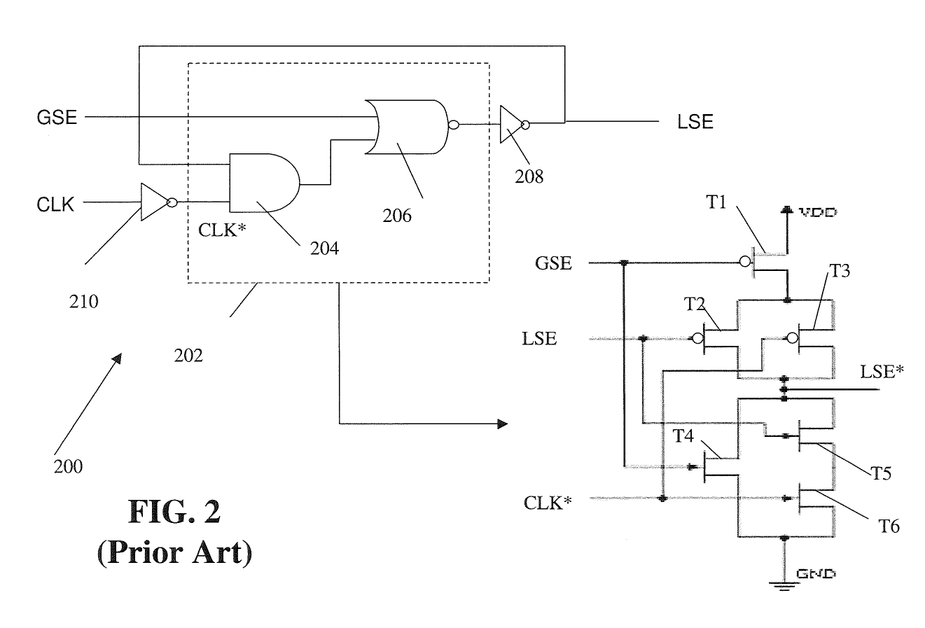

The circuit 300 could replace, for example, circuit 200 shown in FIG. 2. The circuit 300 receives inputs CLK and GSE. These inputs behave, in one embodiment, as illustrated in FIGS. 1A and 1B.

The circuit 300 includes, in one embodiment, a transistor stack 302. This transistor stack 302 can replace the scan enable circuit 202 shown in FIG. 2. The transistor stack 302, in operation, is coupled between power (Vdd) and ground. In more detail, the transistor stack 300 is formed by a first transistor 304, a second transistor 306 and a third transistor 308. As illustrated, the first transistor 304 is coupled between Vdd and the second transistor 306 and the third transistor 308 is coupled between the second transistor 306 and ground.

In one embodiment, the first transistor 304 is a PMOS transistor. In such an embodiment, the source of the first transistor 304 is coupled to Vdd and the drain of the first transistor 304 is coupled to the second transistor 306. It shall be understood that the term “coupled” as used herein does not require (but may include) direct coupling unless otherwise specified.

In one embodiment, the second transistor 306 is also a PMOS transistor. In such an embodiment, the source of the second transistor 306 is coupled to the drain of the first transistor 304. In one embodiment, the third transistor 308 is an NMOS transistor. In such an embodiment, the drain of the third transistor 308 is coupled to the drain of the second transistor 306 and the source of the third transistor 308 is coupled to ground.

In the embodiment illustrated in FIG. 3, the gates of the first and third transistors 304, 306 are coupled to GSE and the gate of the second transistor 306 is coupled to CLK* via clock inverter 311. CLK is the test clock in one embodiment.

At the junction of second and third transistors 306, 308 (node 310) an interim signal SE2 is produced. In one embodiment, SE2 is provided to an output stabilizer 312. In this embodiment, the output stabilizer 312 is formed of two head-to-tail connected inverters 314, 316. In more detail, signal SE2 is provided at a first input of the first inverter 314 at node 310. The output of the first inverter 314 is the signal LSE. To prevent SE2 from floating when the second transistor 306 is off (i.e., receiving a logical 1), the output stabilizer 312 includes the second inverter 316 that is coupled to node 310 and is in the opposite orientation than the first inverter 314. In one embodiment, the second inverter 316 is a weak inverter.

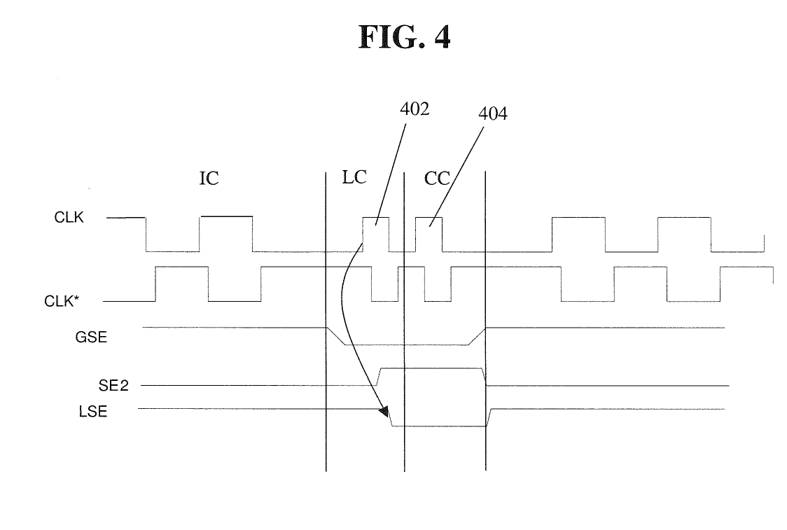

In operation, the circuit 300 illustrated in FIG. 3 produces signals as illustrated in the timing diagram shown in FIG. 4. As discussed above, to be effective, LSE needs to fall after the first at-speed pulse 402 and before the second at-speed pulse 404. As such, the circuit 300 illustrated in FIG. 3 is suitable for at-speed LOS testing and can replace prior art scan enable circuits.

The circuit 300 illustrated in FIG. 3 provides significant size reduction over the prior art. For example, and with reference to both FIGS. 2 and 3, the circuit 300 may be provide for a minimum of 34% area reduction compared to the circuit shown in FIG. 2.

In more detail, the circuit in FIG. 2 requires 10 CMOS transistors (T1-T6+2 CMOS transistors for each inverter 208, 210). The circuit in FIG. 3 requires 9 CMOS transistors (6 from inverters 311, 314, 316 and the first, second and third inverters 304, 306, 308). While only one transistor is saved, the design in FIG. 3 provides significant area savings because the size of the transistors themselves becomes relevant.

For a precise comparison, the transistor count for the circuits shown in FIGS. 2 and 3 shall be expressed in terms PMOS and NMOS transistors used for implementing an inverter. In FIG. 2, when GSE=1, LSE=1 and CLK*=0, two PMOS transistors (T1, T3) come into series. To ensure that the rise time in such a configuration is similar to that of an inverter, the size of each PMOS transistor (T1, T2, T3) should be twice the size of the PMOS transistor used in inverters 208 and 210. Thus, the number of PMOS transistors in the circuit 200 shown in FIG. 2, expressed in terms of PMOS transistors used in inverters (PMOSᵢₙᵥ), is 3*2 PMOSᵢₙᵥ=6 PMOSᵢₙᵥ. Furthermore, when GSE=0, LSE=1 and CLK*=1, two NMOS transistors (T5, T6) come into series. To ensure that the fall time in such a configuration is similar to that of the inverter, the size of each of these two NMOS transistors should be twice the size of the NMOS transistor of inverter (NMOSᵢₙᵥ). Thus, the number of NMOS transistors in circuit 200 expressed in terms of NMOS transistors of inverters=2*2 NMOSᵢₙᵥ+NMOSᵢₙᵥ=5 NMOSᵢₙᵥ. Finally, the circuit 200 includes 2 inverters 208, 210 resulting in 2 additional NMOSᵢₙᵥ and 2 additional PMOSᵢₙᵥ. In sum, the circuit 200 requires the space of 7 NMOSᵢₙᵥ and 8 PMOSᵢₙᵥ. At a 45 nm node, PMOSᵢₙᵥ equals 1.3*NMOSᵢₙᵥ. Thus, the total size is 17.4 NMOSᵢₙᵥ. At a 22 nm node, the ratio is 1.1, leading to an area of 15.8 NMOSᵢₙᵥ.

In contrast, in the circuit 300, the clock inverter 311 and the first inverter 314 combined require the area of 2 PMOSᵢₙᵥ and 2 NMOSᵢₙᵥ. The two PMOS transistors (first transistor 304 and second transistor 306) come into series so they require the area of 4 PMOSᵢₙᵥ to match the rise time of the inverters 311, 314. Only one NMOS transistor (third transistor 308) thus, the number of NMOS transistors, expressed in terms of NMOS transistor of inverter, equals 1 NMOSᵢₙᵥ. The weak inverter (second inverter 316) only requires transistors having a fraction of the width of those in a normal inverter. In one embodiment, the width of the transistors is 0.25 PMOSᵢₙᵥ and 0.25 NMOSᵢₙᵥ. In sum, in the circuit 300 the total transistor area is 3.25 NMOSᵢₙᵥ and 6.25 PMOSᵢₙᵥ. As above, at 45 nm node PMOSᵢₙᵥ equals 1.3*NMOSᵢₙᵥ. Thus, the total size is 11.375 NMOSᵢₙᵥ. For 22 nm, the ratio is 1.1, leading to an area of 10.125 NMOSᵢₙᵥ.

Compared with the area required for the circuit 200 shown in FIG. 2, the circuit 300 shown in FIG. 3 provides a 34.6% area reduction at 45 nm fabrication and 35.91% at 22 nm fabrication.

It shall be understood that if the circuit 300 shown in FIG. 3 is embedded within a scan flip-flop, the clock inverter 311 can be omitted because the inverter used for feeding the master latch (not shown) can serve the same purpose. Furthermore, the first inverter 314 can also be omitted because the scan flip-flop includes an inverter within the multiplexer that can serve the same purpose. In such an embodiment, the circuit 300 will add just 5 CMOS transistors to an existing flop circuit.

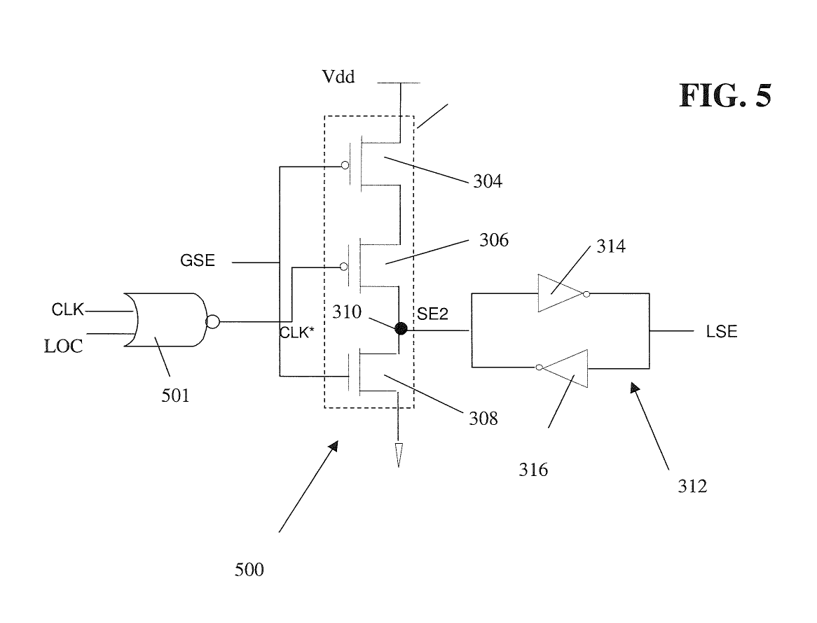

FIG. 5 shows modified circuit 500 based off of circuit 300 that allows both LOC and LOS testing methods to be performed. Here, an LOC signal coupled to a NOR gate 501 shorts the second transistor 306 during LOC. This implementation needs just 11 CMOS transistors.

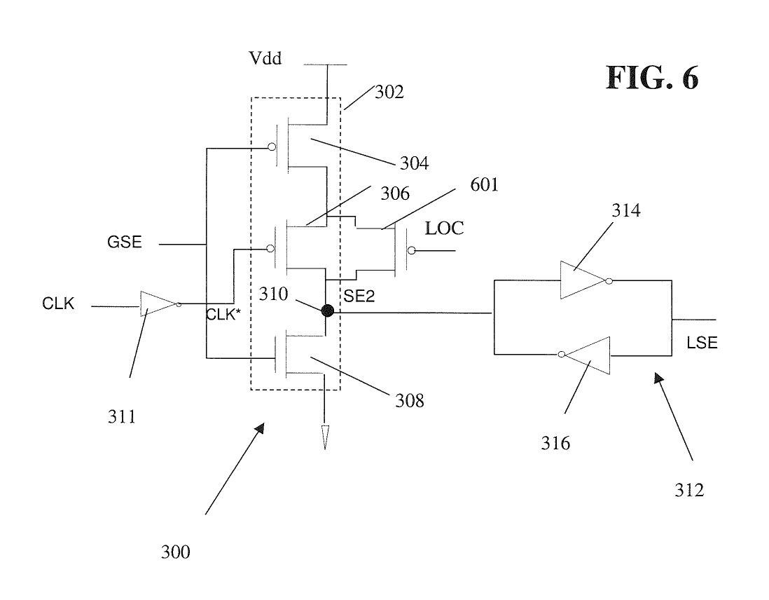

In another embodiment, and referring now to FIG. 6, rather than utilizing the NOR gate 501 (FIG. 5), a shorting transistor 601 across the second transistor 306 and that receives the LOC signal. The shorting transistor 601 is a PMOS in one embodiment. As can be seen in FIG. 6, this configuration requires only 10 CMOS transistors.

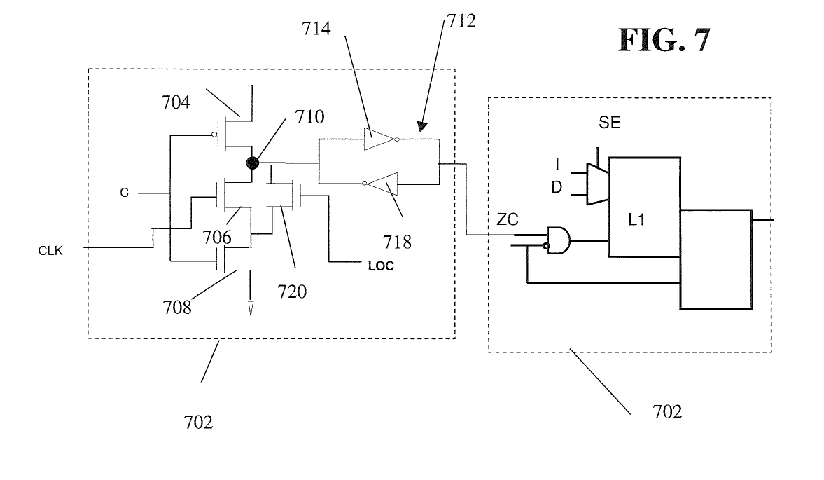

FIG. 7 shows an embodiment of the present invention in combination with a level sensitive scan design (LSSD) latch 701. The operation of the LSSD latch 701 is well known and not describe further herein.

The circuit 702 is utilized to control the C clock pin (illustrated as ZC) of the LSSD latch 701. The circuit 702 of this embodiment includes a first transistor 704, a second transistor 706 and a third transistor 708. As illustrated, the first transistor 704 is coupled between Vdd and the second transistor 706 and the third transistor 708 is coupled between the second transistor 706 and ground.

In one embodiment, the first transistor 704 is a PMOS transistor. In such an embodiment, the source of the first transistor 704 is coupled to Vdd and the drain of the first transistor 704 is coupled to the second transistor 706.

In one embodiment, the second transistor 706 is an NMOS transistor. In such an embodiment, the drain of the second transistor 706 is coupled to the drain of the first transistor 704. In one embodiment, the third transistor 708 is an NMOS transistor. In such an embodiment, the drain of the third transistor 708 is coupled to the source of the second transistor 708 and the source of the third transistor 708 is coupled to ground.

In the embodiment illustrated in FIG. 7, the gates of the first and third transistors 704, 708 are coupled to the static C clock and the gate of the second transistor 704 is coupled to CLK. At the junction of the first and second transistors 704, 708 (node 710) an interim signal is produced. In one embodiment, the interim signal is provided to an output stabilizer 712. In this embodiment, the output stabilizer 710 is formed by two head-to-tail connected inverters 714, 716. In more detail, the interim signal is provided at a first input of the first inverter 714 at node 710. The output of the first inverter 714 is the signal ZC. To prevent the interim signal from floating when the second transistor 706 is off (i.e., receiving a logical 0), the output stabilizer 712 includes the second inverter 716 that is coupled to node 710 and is in the opposite orientation of the first inverter 714. In one embodiment, the second inverter 716 is a weak inverter.

As illustrated, the circuit also includes an optional bypass transistor 720 that shorts the second transistor 706 to allow for LOC operation as described above.

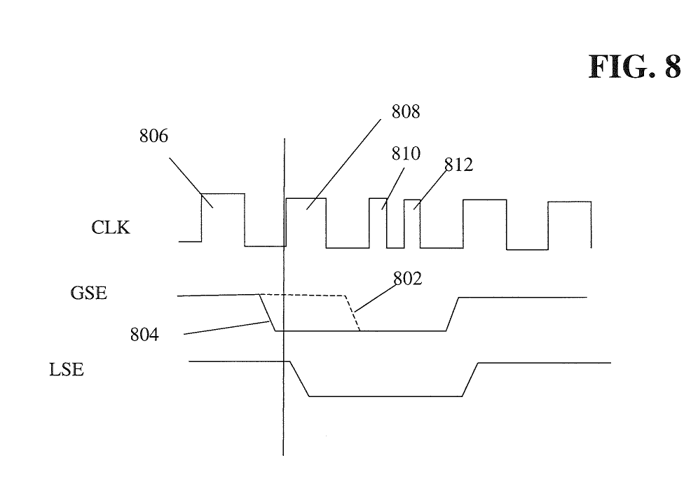

FIG. 8 illustrates a timing diagram showing the industry standard timing of the scan enable signal (dotted line 802) as compared to modified timing of the scan enable 804 according to one embodiment to the present invention. In this embodiment, the GSE is caused to go low between the second to last scan clock pulse 806 and the last scan pulse 808 before the at-speed pulses 810 and 812. Such a modification allows for the circuit of FIG. 3 to be utilized, unaltered, for LOC testing. Accordingly, in one embodiment, a test system is provided that includes a circuit that provides such a change in the GSE signal. Such a circuit (implemented in hardware or software) allows the circuit of FIG. 3 to operate according to the LOC method by providing signal 804. In addition, when the circuit provides an industry standard GSE as indicated by 802 to the circuit in FIG. 3 it operates according to the LOS method.

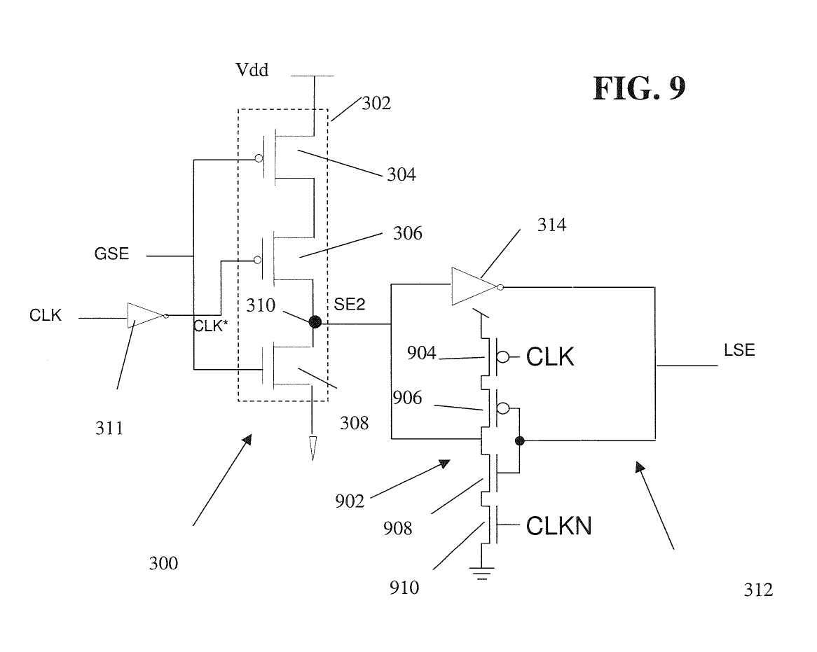

FIG. 9 shows an alternative embodiment of the invention than as shown in FIG. 3 where the weak inverter has been replaced with a feedback element 902. As illustrated, the feedback element 902 includes a first stack transistor 904, a second stack transistor 906, a third stack transistor 908 and a fourth stack transistor 910. As illustrated, the first and second stack transistors 904, 906 are PFET transistors and the third and fourth stack transistors 908, 910 are NFET transistors. In one embodiment, the source of the first stack transistor 904 is coupled to Vdd and the drain thereof is coupled to the source of the second stack transistor 906. The drain of the second stack transistor 906 is coupled to SE2 and to the drain of the third stack transistor 908. The source of the third stack transistor 908 is coupled the drain of the fourth stack transistor 910 which, in turn, has its source coupled to ground. The gate of the first stack transistor 904 is coupled to the test clock (CLK) and the gate of the fourth stack transistor 910 is coupled to the CLK*. The gates of the second and third stack transistors 906, 908 are both coupled to LSE.

The feedback element 902 functions as a tri-state of the feedback component. In operation, when CLK is low, feedback element 902 is active, and node SE2 is used to store the high value of Scan Enable. The SE2 node can be brought low at any time, by activating the GSE. When the CLK is active, the feedback path is tri-stated so that, in the case when GSE is low, node SE2 will easily be driven high. The input driver 302 can easily transition node SE2 to the high state, since, when the feedback is tri-stated, only capacitance on node SE2 is being driven. This provides the benefit of improving the performance of the rising transition of node SE2, the possibility to reduce the size of the input driver 302, and most importantly, an improvement in low voltage functionality when driving node SE2 to the high state. Any one of these, or a combination of the three, may be realized, based upon proper design for the size of the transistors involved.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

The flow diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

What is claimed is:

1. A circuit for providing a local scan enable signal, the circuit comprising:
a first transistor having a first gate coupled to a general scan enable signal, a first source and a first drain;
a second transistor having a second gate coupled to a scan clock, a second source coupled to the first drain and a second drain;
a third transistor having a third gate coupled to the general scan enable signal, a third drain coupled to the second drain and a third source; and
an output stabilizer coupled to the second drain, the output stabilizer including a first inverter and a second feedback element.

2. The circuit of claim 1, wherein the first and second transistors are NMOS transistors.

3. The circuit of claim 1, wherein the third transistor is a PMOS transistor.

4. The circuit of claim 1, wherein the first source is coupled to power and the third source is coupled to ground.

5. The circuit of claim 1, further comprising:
a shorting transistor coupled across the second transistor to short the second transistor upon receipt of a load off capture signal.

6. The circuit of claim 1, wherein the feedback element is a weak inverter coupled to the first inverted in an opposite orientation.

7. The circuit of claim 1, wherein the feedback element is a configured to operate as tri-state element.

8. The circuit of claim 1, further comprising:
a clock inverter coupled to the second gate.

9. The circuit of claim 1, further comprising:
a NOR gate coupled to the second gate and receiving the scan clock signal and a load off capture.

10. A circuit for providing a local scan enable signal, the circuit comprising:
a first transistor having a first gate coupled to a general scan enable signal, a first source and a first drain;
a second transistor having a second gate coupled to a scan clock, a second drain coupled to the first drain and a second source;
a third transistor having a third gate coupled to the general scan enable signal, a third drain coupled to the second source and a third source; and
an output stabilizer coupled to the first drain, the output stabilizer including a first inverter and a second inverter coupled together in opposite orientations.

11. The circuit of claim 10, wherein the first transistor is an NMOS transistor.

12. The circuit of claim 10, wherein the second and third transistors are PMOS transistors.

13. The circuit of claim 10, wherein the first source is coupled to power and the third source is coupled to ground.

14. The circuit of claim 10, further comprising:
a shorting transistor coupled across the second transistor to short the second transistor upon receipt of a load off capture signal.

15. The circuit of claim 10, wherein the second inverter is a weak inverter.

16. The circuit of claim 10, further comprising:
a clock inverter coupled to the second gate.

17. A test system comprising:
a first circuit for providing a local scan enable signal, the first circuit comprising:
a first transistor having a first gate coupled to a general scan enable signal, a first source and a first drain;
a second transistor having a second gate coupled to a scan clock, a second source coupled to the first drain and a second drain;
a third transistor having a third gate coupled to the general scan enable signal, a third drain coupled to the second drain and a third source; and
an output stabilizer coupled to the second drain, the output stabilizer including a first inverter and a second inverter coupled together in opposite orientations;
a second circuit for providing the general scan enable signal, the second circuit configured to provide the general scan enable signal according to a first timing relationship when the first circuit is operating in a launch off scan mode and a second timing relationship when the first circuit is operating in a launch off capture mode.

18. The test system of claim 17, wherein the general scan goes from high to low between the second to last scan clock pulse and the last scan pulse before a first at-speed clock pulse in the second timing relationship and the general scan enable goes from high to low after the last scan clock pulse before the first at-speed clock pulse.
